(19) United States
(12) Patent Application Publication
(10) Pub. No.: US 2014/0346993 A1
(43) Pub. Date: Nov. 27, 2014

(54) Fan motor driving device, driving method, and cooling device and electronic machine using the same

(71) Applicant: ROHM CO., LTD., Kyoto (JP)

(72) Inventor: Tomofumi MISHIMA, Kyoto (JP)

(73) Assignee: ROHM CO., LTD., Kyoto (JP)

(21) Appl. No.: 14/120,365

(22) Filed: May 14, 2014

(30) Foreign Application Priority Data
May 14, 2013 (JP) 2013-102584

(51) Int. Cl. H02P 6/16; H05K 7/20

(52) U.S. Cl. CPC H02P 6/16; H05K 7/20209
USPC 318/400.38; 165/121

(57) ABSTRACT

A fan motor driving device driven based on a pair of out-of-phase Hall signals may include a first driving portion, configured to (i) amplify a difference of the pair of the Hall signals with a first polarity and generate a first control signal, and (ii) switch between a driving status and a regeneration status; a second driving portion, configured to (i) amplify the difference of the pair of the Hall signals with a second polarity, and generate a second control signal, and (ii) switch between a driving status and a regeneration status; and a regeneration controller, controlling statuses of the first driving portion and the second driving portion, respectively.

### CROSS REFERENCE TO RELATED APPLICATIONS

The present invention claims priority under 35 U.S.C. §119 to Japanese Application No. 2013-102584 filed May 14, 2013, the entire content of which is incorporated herein by reference.

JP0731190 and JP 2001-284868 are incorporated herein by reference in its entirety for all purposes.

### BACKGROUND

The invention is related to a fan motor driving technology.

As high speeding of personal computers or work stations in these years, acting speed of large scale integrated circuits (LSIs) such as central processing units (CPUs) or digital signal processors (DSPs) for algorithm processing is increasing. In such LSI, heat generation increases along with the increasing acting speed and real-time clock frequency. The existing heat generated from the LSI results in loss of thermal control to the LSI or affects surrounding circuits. Therefore, proper cooling of a heat generating body, LSI, for example, (hereinafter referred to as LSI) becomes an extremely important technology.

As an example for cooling LSI, an air cooling method using a cooling fan is provided. In this method, a cooling fan is opposingly disposed to a surface of the LSI, and cooling air is transmitted to the surface of the LSI, for example.

Driving methods such as conversion driving and bridged transless (BTL) driving are known to drive a fan motor.

FIGS. 1(a) and (b) illustrate a circuit diagram and an acting waveform diagram of a fan motor driving device using the conversion driving method. A pair of Hall signals, V_{H+} and V_{H-}, from a Hall element (also called a Hall sensor) 104 are input to Hall terminals, H+ and H−, of a fan motor driving device 2r. Based on the Hall signals, H+ and H−, a fan motor 102 is driven by the driving device 2r. The pair of the out-of-phase Hall signals, H+ and H−, are sinusoidal waves, indicating a location of a rotor of the fan motor 102.

A Hall bias voltage V_{HB} is generated by a reference voltage source 210, and provided to the Hall element 104. Amplitudes of the Hall signals, H+ and H−, are corresponding to the Hall bias voltage V_{HB}. The Hall signals, H+ and H−, are compared by a Hall comparator 214, and a time sequence for phase switching is examined by the Hall comparator 214. A difference between the Hall signals, H+ and H−, is amplified by a Hall amplifier 212.

A comparator 216 is disposed for setting a regeneration period. A setting voltage V_{ADJ} may be input from the outside, and a regeneration period may be adjusted by a designer. The output voltage of the Hall amplifier 212 and the setting voltage V_{ADJ} indicating the length of the regeneration period are compared by the comparator 216, and the crossing time sequences thereof are used for setting the regeneration period.

A control signal S13 indicating a connecting or disconnecting status between each transistor of the H bridging circuit 240 is generated by a logic portion 220 based on an output S11 of the Hall comparator 214 and an output S12 of the comparator 216. The H bridging circuit 240 is controlled by a pre-driver 230 based on the control signal S13.

FIG. 1(b) shows driving voltages V_{OUT1}, V_{OUT2} and coil current I_{COIL} from top to bottom. Prior to time t1, the driving voltage V_{OUT2} is at high voltage level V_{DD}, and the driving voltage V_{OUT1} is at low voltage level V_{GND}. Prior to time t1, the coil current I_{COIL} is negative, flowing in a direction from OUT2 toward OUT1 (herein referred to a second direction).

At time t1, if the output S11 of the Hall comparator 214 changes, the driving voltage V_{OUT2} is switched to a low voltage level. After time t1, the coil current I_{COIL} immediately and continuously flows along the second direction in the coil of the fan motor 102 due to the counter electromotive force thereof. If the driving voltage VOUT1 is immediately transformed into a high voltage level under the condition in which there is residual energy in the coil, the coil current I_{COIL} flows to a capacitor C1 connected to the terminal VDD via a body diode of a transistor forming a bridging circuit. Accordingly, it is not desired that the power source voltage V_{DD} increases, and also the driving voltage V_{OUT1} increases.

To prevent the power source voltage V_{DD} and the driving voltage V_{OUT1} from increasing, a regeneration period T_{RGN} is inserted. During the regeneration period TRGN, two lower side transistors of the bridging circuit 240 are connected, and both the driving voltages V_{OUT1} and V_{OUT2} are fixed as low voltage levels. During the regeneration period T_{RGN}, the coil current I_{COIL} circulates in a loop of the coil including the fan motor 102, the two lower side transistors, and ground.

The length of the regeneration period T_{RGN} must be set as a length for capable of adequately dissipating energy stored in the coil. Herein, if the length of the regeneration period T_{RGN} is optimized based on the common turning number, the regeneration period T_{RGN} is insufficient due to the coil current increases under the condition when, for example, the power source is connected or a protecting action is locked, such that the power source voltage V_{DD} and the output voltage V_{OUT} increase. If the regeneration period T_{RGN} is allowed be longer in order to avoid such situation, efficiency becomes poor.

Thus, the conversion driving is more efficient than the following BTL driving, and on the other hand, it is difficult to set the length of the regeneration period T_{RGN}. Further, as shown in FIG. 1(b), since there is an inflection point present in the coil current I_{COIL}, the issue of noises resulting from electromagnetic noises is present.

Hereafter, the BTL driving is illustrated. FIGS. 2(a) and 2(b) illustrate a circuit diagram and an action waveform diagram of a fan motor driving device using the BTL driving method. The difference of the Hall signals, H+ and H−, is amplified by a first amplifier 320 and a second amplifier 322, respectively, with opposing polarities to each other. An output signal of the first amplifier 320 is received by a first buffer 330, the driving voltage V_{OUT1} corresponding to the output signal is applied to one end of the fan motor 102. An output signal of the second amplifier 322 is received by a second buffer 332, and the driving voltage V_{OUT2} corresponding to the output signal is applied to the other end of the fan motor 102. Pulse signals with modulated pulse widths are generated by the logic portion 340 according to the target torque (target turning number) of the fan motor 102, and the outputs of the first buffer 330 and the second buffer 332 are converted by the logic portion 340 according to the pulse signals.

FIG. 2(b) shows the driving voltages V_{OUT1}, V_{OUT2}, and the coil current I_{COIL} from top to bottom. In the BTL driving method, the driving voltages V_{OUT1} and V_{OUT2} vary continuously and smoothly, so as to inhibit that the power source voltage V_{DD} and the driving voltage V_{OUT} increase along with the switching of phases. Additionally, since the coil current I_{COIL} varies smoothly without an inflection point, it is advantageous that there are less noises resulting from electromagnetic noise signals.

On the other hand, in the BTL driving method, it is an issue that there is more power consumption in the switching period of phases. The greater the power consumption, the greater the heat generation of an IC (integrated circuit). Therefore, in comparison with the conversion driving method, the BTL driving method is not suitable for a motor with large current.

### BRIEF SUMMARY OF THE INVENTION

Accordingly, the conversion driving method and the BTL driving method respectively have opposite advantages and drawbacks. Hence, conventionally, a designer of a cooling fan module or an electronic machine has to select a driving method suitable for each platform, but it is difficult to retain both silent and high efficiency performance.

The present invention is completed in such condition, and one of exemplary embodiments is to provide a motor driving device achieving silent and high efficiency.

One aspect of the present invention is related to a fan motor driving device. The fan motor driving device drives a fan motor based on a pair of out-of-phase Hall signals from a Hall element, indicating locations of rotors, which drive symmetric fan motors. The fan motor driving device includes: a first driving portion configured to (i) amplify a difference of a pair of Hall signals with a first polarity to generate a first control signal, and (ii) switch between a driving status and a regeneration status; a second driving portion configured to (i) amplify a difference of a pair of Hall signals with a second polarity to generate a second control signal, and (ii) switch between a driving status and a regeneration status; and a regeneration controller for controlling a status of each of the first driving portion and the second driving portion.

A first driving voltage corresponding to the first control signal is applied to one end of a coil of the fan motor by the first driving potion under (ii-1) the driving status, and the current flowing to the coil of the fan motor is regenerated by an output segment of the first driving portion under (ii-2) the regeneration status.

A second driving voltage corresponding to the second control signal is applied to the other end of the fan motor by the second driving portion under (ii-1) the driving status, and the current flowing to the coil of the fan motor is regenerated by an output segment of the second driving portion under (ii-2) the regeneration status.

If the first and the second driving portions are set as the driving status in the switching period of phases (also referred to a phase transition period), the motor driving device may perform actions as under the BTL driving method. On the contrary, if the first and the second driving portions are set as the regeneration status in the phase transition period, the motor driving device may perform actions as under the conversion-like driving method. According to this aspect, the status of the first driving portion and the second driving portion is properly controlled by the regeneration controller, so as to achieve silent and high efficiency.

A first regeneration period may be set at the downward slope of the first control signal by the regeneration controller, and during the first regeneration period, the first driving portion is set to be in the regeneration status, and periods other than the first generation period are set to be in the driving status by the regeneration controller. Also, a second regeneration period may be set at the downward slope of the second control signal by the regeneration controller, and during the second regeneration period, the second driving portion is set to be in the regeneration status, and periods other than the second generation period are set to be in the driving status by the regeneration controller.

The regeneration controller also may set longer duration for the first regeneration period and the second regeneration period when the turning number of the fan motor is greater.

Under the situation that the turning number of the fan motor is greater and the noise resulting from electromagnetic noise signals is not an issue, efficiency is increased and heat generation is reduced by increasing the duration of the regeneration period; and under the situation that the turning number of the fan motor is lower and the noise resulting from electromagnetic noise signals should be reduced, the noise may be eliminated by reducing the duration of the regeneration period, i.e. increasing the duration of the soft conversion period of the slope.

Alternatively, the first driving portion under the regeneration status fixes the first driving voltage at a predetermined voltage regardless of what the first control signal is; and the second driving portion under the regeneration status fixes the second driving voltage at a predetermined voltage regardless of what the second control signal is.

In such situation, the coil current may be regenerated via the lower side transistor at the output segment.

Alternatively, the first driving portion and the second driving portion under the regeneration status have outputs with high resistance.

In such situation, the coil current may be regenerated via the diode body of the transistor at the output segment.

The first driving portion may also convert the first driving voltage as the following embodiment, i.e. under the regeneration status, the envelope of the first driving voltage varies based on the first control signal, and the duty cycle of the first driving voltage gradually varies. The second driving portion may also convert the second driving voltage as the following embodiment, i.e. under the regeneration status, the envelope of the second driving voltage varies based on the second control signal, and the duty cycle of the second driving voltage gradually varies.

In such situation, during a period that the first driving voltage (the second driving voltage) is at a low voltage level, the coil current is regenerated. According to this embodiment, substantially, since time for the coil current regeneration gradually varies, the silent property may be enhanced in comparison with the situation that the first driving voltage (the second driving voltage) is fixed at the low voltage level.

The regeneration controller may also include: a first comparator for comparing a threshold voltage corresponding to the turning number of the fan motor with the first control signal, and generating a first examining signal if the first control signal is determined to be lower; a second comparator for comparing a threshold voltage with the second control signal, and generating a second examining signal if the second control signal is determined to be lower; and a logic portion for switching the first driving portion to be in a regeneration status if the first examining signal is generated, and switching the second driving portion to be in the regeneration status if the second examining signal is generated.

According to the embodiment, the greater the threshold voltage, the greater the duration of the first regeneration period and the second regeneration period.

The regeneration controller may also control the first driving portion and the second driving portion, respectively, according to an instruction signal indicating the turning number of the fan motor.

The instruction signal may also be a voltage of a thermal-sensitive resistor, whose voltage is generated corresponding to an ambient temperature. Alternatively, the instruction signal may be an analog signal indicating the turning number of the fan motor or a pulse signal of a duty cycle corresponding to the target turning number (target torque).

The instruction signal may be a lower value if the target value of the turning number of the above fan motor is greater. The regeneration controller may further include an inverting amplification circuit, which generates the threshold voltages by inversely amplifying the instruction signal.

The regeneration controller may also control the first driving portion and the second driving portion, respectively, according to an examining signal of the current turning number of the fan motor. The examining signal may also be a frequency generator (FG) signal proportional to the turning number.

The regeneration controller may also control the first driving portion and the second driving portion, respectively, according to the current entering to the fan motor.

The first driving portion may also include a first Hall amplifier for generating a first control signal by non-inversely amplifying a difference of a pair of Hall signals. The second driving portion may also include a second Hall amplifier for generating a second control signal by inversely amplifying a difference of a pair of Hall signals.

The gain of the first Hall amplifier may also be set according to the following descriptions, i.e. the first control signal being inclined in the phase switching period and flat in period other than the phase switching period. The gain of the second control signal may also be set according to the following descriptions, i.e. the second control signal being inclined in the phase switching period and flat in period other than the phase switching period.

It is another aspect of the present invention to provide a cooling device. The cooling device includes: a fan motor, a Hall element for generating a pair of Hall signals indicating a location of a rotor of the fan motor; and any one of the above-mentioned fan motor driving devices for driving the fan motor based on the pair of Hall signals.

It is another aspect of the present invention to provide an electronic machine. The electronic machine includes: a processor; a fan motor disposed opposingly to the processor; a Hall element for generating a pair of Hall signals indicating a location of a rotor of the fan motor; and any one of the above-mentioned fan motor driving devices for driving the fan motor based on the pair of Hall signals.

Further, any combinations of the above essential components or alternations and replacements between the essential components in the methods, devices and systems of the present invention are also embodiments of the present invention.

According to an embodiment of the present invention, both outstanding silent property and enhanced efficiency can be achieved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1(a) and 1(b) illustrate a circuit diagram and an acting waveform diagram of a fan motor driving device using the conversion driving method.

FIGS. 2(a) and 2(b) illustrate a circuit diagram and an acting waveform diagram of a fan motor driving device using the BTL driving method.

FIG. 3 is a schematic view showing an electronic machine implementing a fan motor driving device according to an embodiment.

FIG. 4 is a waveform diagram of the action of the driving device shown in FIG. 3.

FIGS. 5(a) and 5(b) are waveform diagrams showing difference action modes of the driving device.

FIG. 6 is a circuit diagram of a regeneration controller according to an embodiment.

FIG. 7 shows actions of the regeneration controller of FIG. 6.

FIG. 8(a) shows the power consumption of the driving device according to an embodiment, and FIG. 8(b) shows a frequency spectrum of noises of the driving device.

FIGS. 9(a) and 9(b) are waveforms diagrams showing the driving voltage V_{OUT1} (V_{OUT2}) of the fourth and the fifth examples.

### DETAILED DESCRIPTION

The present invention is illustrated in the following descriptions based on embodiments and referring to drawings. The same or equivalent configuration elements, components and processing steps have the same reference numerals, and the repeated descriptions are omitted adequately. Further, embodiments are exemplary and not intended to limit the present invention. All features in the embodiments and combinations thereof are not necessary for the nature of the present invention.

In the specification of the present application, “connection status between a component A and a component B” is referred to that the component A is physically in direct contact with the component B, and also includes the indirect connection that other components may be disposed between the component A and the component B without substantially affecting the electrical connection status and damaging the efficacy or effects of the combination of the components.

Similarly, “a component C disposed between a component A and a component B” is referred to the direct connection of the component A and the component C or the direct connection of the component B and the component C, and also includes the indirect connection that other components may be disposed between the component A and the component B without substantially affecting the electrical connection status and damaging the efficacy or effects of the combination of the components.

A computer such as a personal computer or a work station and a fan motor driving device (also abbreviated as a driving device) for driving a fan motor for cooling a CPU, for example, are used for illustrating an embodiment of the present invention.

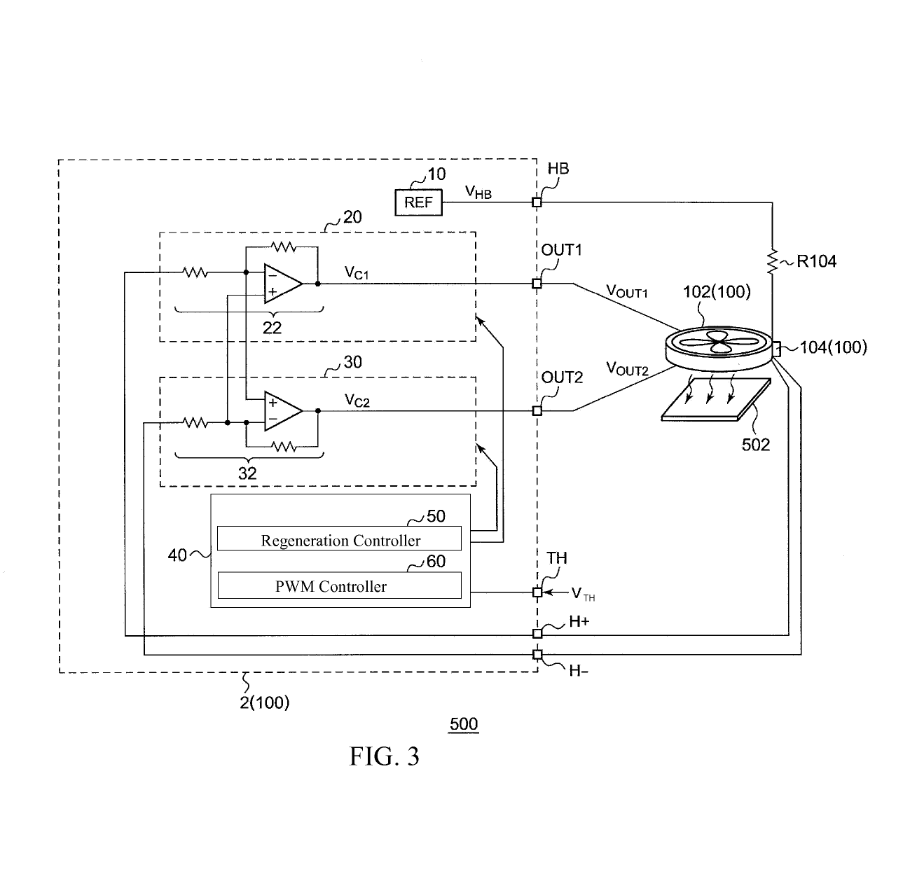

FIG. 3 is a schematic view showing an electronic machine 500 implementing a fan motor driving device 2.

An electronic machine 500 is a desktop or laptop personal computer, a work station, a game machine or a household electrical appliance such as a refrigerator or a television, and includes an object to be cooled which is a processor 502 such as a CPU, DSP or GPU (graphic processing unit); and a cooling device 100 for cooling the processor 502. The cooling device 100 cools the processor 502 by air blowing.

The cooling device 100 includes a fan motor 102, a Hall element 104 and a driving device 2.

The fan motor 102 is disposed to be close to the processor 502 to be cooled. The driving device 2 drives the fan motor 102 based on an instruction signal S1 indicating a torque (turning number) of the fan motor 102. The cooling device 100 is commercially sold upon modularization.

The fan motor 102 is a DC (direct current) motor. The Hall element 104 is installed in the fan motor 102. The Hall element 104 generates a pair of out-of-phase Hall signals, V_{H+} and V_{H-}, indicating a location of a rotor of the fan motor 102. A bias terminal of the Hall element 104 is connected to the Hall bias (HB) terminal via a bias resistor R104.

Further, one end of a coil (not shown) of the fan motor 102 is connected to a first output terminal OUT1 of the driving device 2, and the other end of the coil is connected to a second output terminal OUT2 of the driving device 2.

The driving device 2 includes a reference voltage source 10, a first driving portion 20, a second driving portion 30, and a control unit 40 disposed and integrated on a semiconductor substrate. The term “integrated” includes the situation that all components of a circuit are formed on a semiconductor substrate, or a situation that the essential components of the circuits are integrated. Also, a part of resistors or capacitors may be disposed outside of the semiconductor substrate for regulating a circuit constant.

A Hall bias voltage V_{HB} of a predetermined level is generated by the reference voltage source 10, and provided to a bias terminal of the Hall element 104.

The first driving portion 20 is configured to (i) amplify a difference of the pair of the Hall signals, V_{H+} and V_{H-}, with a first polarity, and generate a first control signal V_{C1}, and to (ii) switch between a driving status φ_{DRV} and a regeneration status φ_{RGN}. The first driving portion 20 is configured to (ii-1) apply a first driving voltage V_{OUT1} corresponding to the first control signal V_{C1} to one end of the coil of the fan motor 102 under the driving status φ_{DRV}, and (ii-2) fix the first driving voltage V_{OUT1} to a predetermined level under the regeneration status φ_{RGN} regardless of what the first control signal V_{C1} is.

The first control signal has an inclined waveform in the phase switching period (also referred to a phase transition period), and has a flat waveform in periods (driving periods) other than the phase switching period.

The second driving portion 30 is configured to (i) amplify a difference of the pair of the Hall signals, V_{H+} and V_{H-}, with a second polarity, and generate a second control signal V_{C2}, and to (ii) switch between a driving status φ_{DRV} and a regeneration status φ_{RGN}. The second control signal V_{C2} and the first control signal V_{C1} are out-of-phase, i.e. signals with 180 degrees of phase shift. It is similar to the first control signal V_{C1} that the second control signal has an inclined waveform in the phase switching period, and has a flat waveform in periods other than the phase switching period

The second driving portion 30 is configured to (ii-1) apply a second driving voltage V_{OUT2} corresponding to the second control signal V_{C2} to one end of the coil of the fan motor 102 under the driving status φ_{DRV}, and (ii-2) fix the second driving voltage V_{OUT2} to a predetermined level under the regeneration status φ_{RGN} regardless of what the first control signal V_{C2} is.

The firsts driving voltage V_{OUT1} and the second driving voltage V_{OUT2} under the regeneration status may also be at a low voltage level (ground voltage).

The control unit 40 includes a regeneration controller 50 and a PWM (pulse width modulation) controller 60. The regeneration controller 50 controls the statuses of the first driving potion 30 and the second driving portion 40, respectively.

The PWM controller 60 is configured for controlling the turning number (torque) of the fan motor 102. The instruction signal V_{TH} indicating the turning number of the fan motor 102 is input to the PWM controller 60. For example, the instruction signal V_{TH} may also be a voltage of a thermal sensitive resistor indicating the temperature of the object to be cooled i.e. a CPU 502.

The PWM controller 60 generates a pulse signal S_{PWM} having a duty cycle corresponding to the instruction signal V_{TH}. The first driving portion 20 is configured such that the output voltage V_{OUT1} thereof is switched according to the pulse signal S_{PWM}. In other words, when the duty cycle of the pulse signal S_{PWM} is 100%, the first driving voltage V_{OUT1} is the same signal as the first control signal V_{C1}, and when the duty cycle of the pulse signal S_{PWM} is less than 100%, the first driving voltage V_{OUT1} has a waveform obtained from taking the first control signal V_{C1} as the envelop. Regarding the second driving portion 30, it is the same as the above description.

In the present embodiment, the first regeneration period T_{RGN1} is set as to overlap with the terminal of the downward slope of the first control signal V_{C1} by the regeneration controller 50, and the first driving portion 20 is set to be in the regeneration status φ_{RGN} during the first regeneration period T_{RGN1} and set to be in the driving status φ_{DRV} in the periods other than the first regeneration period T_{RGN1}.

Further, the second regeneration period T_{RGN2} is set as to overlap with the terminal of the downward slope of the second control signal V_{C2} by the regeneration controller 50, and the second driving portion 30 is set to be in the regeneration status φ_{RGN} during the second regeneration period T_{RGN2} and set to be in the driving status φ_{DRV} in the periods other than the second regeneration period T_{RGN2}.

In a preferred embodiment, the regeneration controller 50 sets the first regeneration period T_{RGN1} and the second regeneration period T_{RGN2} to be longer when the turning number of the fan motor 102 is greater.

The first driving portion 20 includes a first Hall amplifier 22.

The first Hall amplifier 22 generates a first control signal V_{C1} by non-inversely amplifying a difference of a pair of Hall signals, V_{H+} and V_{H-}. It is desired for the gain of the first Hall amplifier 22 to follow the following rule, that is, the first control signal V_{C1} being inclined in the phase switching period, and being flat in other periods.

The first Hall amplifier 22 uses the first control signal V_{C1} as a first driving voltage V_{OUT1}, and outputs the first driving voltage V_{OUT1} to the coil of the fan motor 102. The first Hall amplifier 22 transfers the output V_{OUT1} according to the pulse signal S_{PWM} from the PWM controller 60. Further, the first Hall amplifier 22 fixes the level of the output V_{OUT1} at a predetermined voltage during the first regeneration period T_{RGN1} under the regeneration status instructed by the regeneration controller 50.

The second driving portion 30 is configured similarly to the first driving portion 20. Specifically, the second driving portion 30 includes a second Hall amplifier 32. The second Hall amplifier 32 generates a second control signal V_{C2} by inversely amplifying a difference of a pair of Hall signals, V_{H+} and V_{H-}. It is desired for the gain of the second Hall amplifier 32 to follow the following rule, that is, the second control signal V_{C2} being inclined in the phase switching period, and being flat in other periods.

The second Hall amplifier 32 uses the second control signal V_{C2} as a second driving voltage V_{OUT2}, and outputs the second driving voltage V_{OUT2} to the coil of the fan motor 102. The second Hall amplifier 32 transfers the output V_{OUT2} according to the pulse signal S_{PWM} from the PWM controller 60. Further, the second Hall amplifier 32 fixes the level of the output V_{OUT2} at a predetermined voltage during the second regeneration period T_{RGN2} under the regeneration status instructed by the regeneration controller 50.

Further, a buffer may be inserted at a rear segment of the first Hall amplifier 22 and the second Hall amplifier 32, respectively. In such situation, each buffer may transfer the output V_{OUT2} according to the pulse signal S_{PWM} from the PWM controller 60. Further, the buffer may also fix the level of the output V_{OUT2} at a predetermined voltage during the second regeneration period T_{RGN2} under the regeneration status instructed by the regeneration controller 50.

There is no limitation to the configurations of the first Hall amplifier 22 and the second Hall amplifier 32, but it is desired that the first Hall amplifier 22 and the second Hall amplifier 32 have the same configuration.

The configuration of the driving device 2 is discussed in the above descriptions, and the actions of the driving device 2 are discussed as follows.

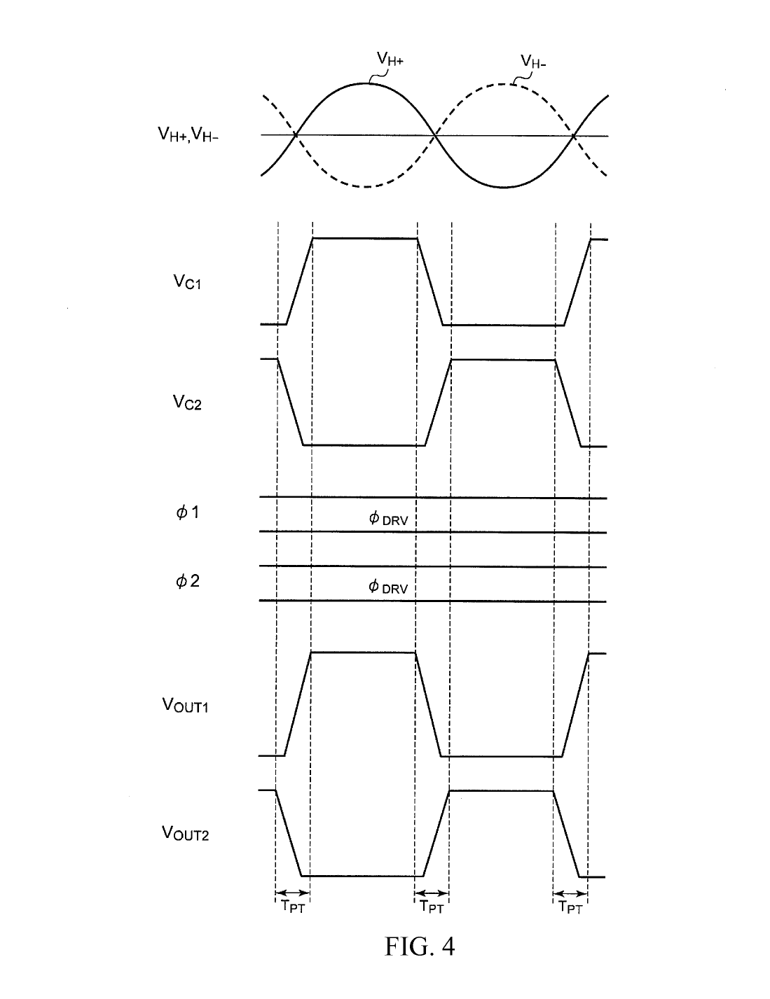

FIG. 4 is a waveform diagram of the driving device 2 shown in FIG. 3. In FIG. 4, the duration of the first regeneration period T_{RGN1} and the second regeneration period T_{RGN2} are set to zero, and both of the first driving portion 20 and the second driving portion 30 are set to have the waveform under the driving status φ_{DRV}. Herein, for better understanding, the duty cycle of the pulse signal S_{PWM} is set to 100%.

FIG. 4 shows the Hall signals V_{H+}, V_{H-}, the status φ₁ of the first driving portion 20, the status φ₂ of the second driving portion 30, the first control signal V_{C1}, the second control signal V_{C2}, the first driving voltage V_{OUT1}, and the second driving voltage V_{OUT2} from top to bottom.

The first control voltage V_{C1} and the second control voltage V_{C2} are inclined during the phase switching period T_{PT}. Persons skilled in the art would understand that the first control signal V_{C1} and the second control signal V_{C2} have waveforms corresponding to the gain and the power source voltage of the first Hall amplifier 22 and the second Hall amplifier 32, as well as the bias level and amplitude of the Hall signals.

If the first driving portion 20 and the second driving portion 30 are fixed under the driving status φ_{DRV}, the driving voltage V_{OUT1} and the driving voltage V_{OUT2} are the same as the control voltages V_{C1} and V_{C2}, respectively. In other words, this acting mode has the same effect as the BTL driving method.

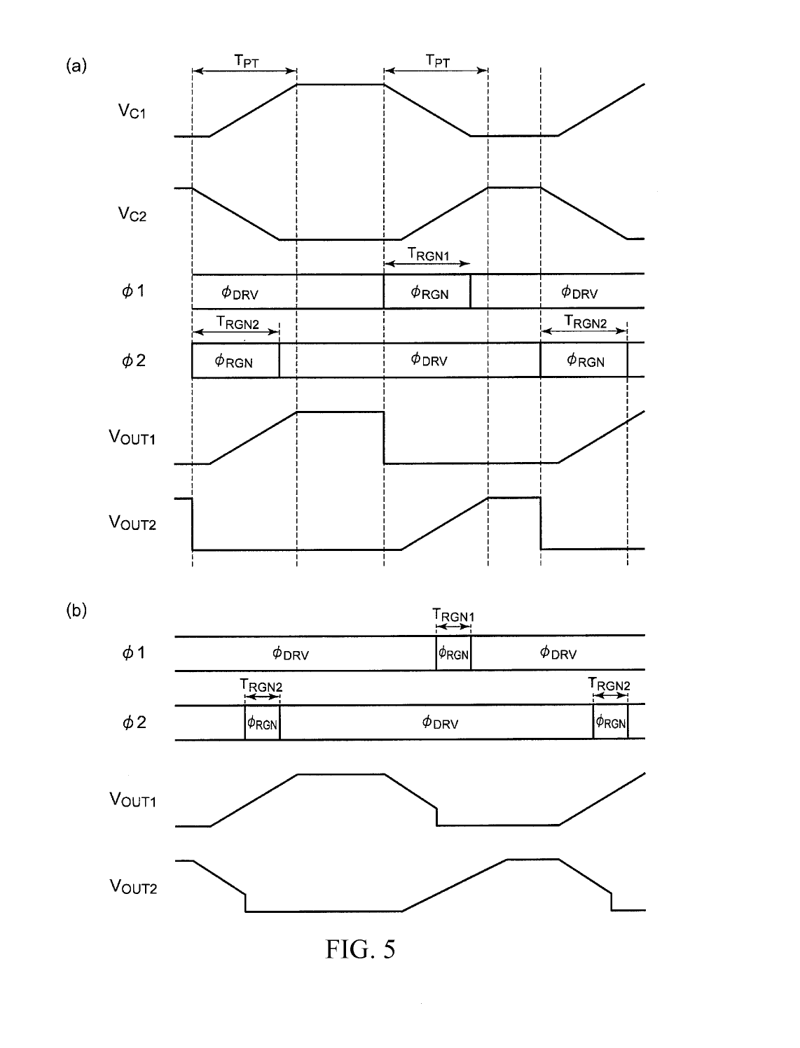

FIGS. 5(a) and 5(b) show waveforms of the driving device 2 under different acting modes. As shown in FIG. 5(a), during the entire period of the downward slope of each of the first control signal V_{C1} and the second control signal V_{C2}, the first driving portion 20 and the second driving portion 30 are set under the regeneration status φ_{RGN}. Under such acting mode, in the phase switching period T_{PT}, the output of one of the first driving portion 20 and the second driving portion 30 is fixed at a low level. Hence, the conversion-like driving method can be achieved.

As shown in FIG. 5(b), during a portion of the period of the downward slope of each of the first control signal V_{C1} and the second control signal V_{C2}, the first driving portion 20 and the second driving portion 30 are set under the regeneration status φ_{RGN}. The mode shown in FIG. 5(b) can be understood as the intermediate status of the mode shown in FIG. 4 and FIG. 5(a).

The actions of the driving device 2 are discussed in the above descriptions.

In accordance with the driving device 2, when the first driving portion 20 and the second driving portion 30 are set under the driving status φ_{DRV} in the phase switching period T_{PT} as shown in FIG. 4, the motor driving device 2 performs the BTL driving method. Hence, the driving device 2 is allowed to perform with low noises.

In the contrary, when one of the first driving portion 20 and the second driving portion 30 is set under the regeneration status φ_{RGN} during the phase switching period T_{PT}, the motor driving device 2 is allowed to perform as under the conversion-like driving method. Hence, the efficiency of the second driving device 2 is improved.

In other words, according to driving device 2, the statuses of the first driving portion 20 and the second driving portion 30 are properly controlled by the regeneration controller 50, and it is thus advantageous to perform as under both the conversion-like driving method and the BTL driving method, so as to achieve outstanding silent property and improved efficiency.

Further, when the turning number of the fan motor 102 is greater, the durations of the first regeneration period T_{RGN1} and the second regeneration period T_{RGN2} are set longer. Therefore, under the situation that the turning number of the fan motor 102 is greater and the noises resulting from electromagnetic noises is not an issue, efficiency can be improved and heat generation is reduced by increasing the duration of the regeneration status φ_{RGN}. On the other hand, under the situation that the turning number of the fan motor 102 is lower and the noises resulting from electromagnetic noises need to be reduced, the silent property can be improved by reducing the duration of the regeneration status φ_{RGN}, i.e. increasing the soft conversion period of the slope.

Further, the shift of the current phase can be prevented by setting the regeneration period only at the downward slope.

In the situation that the fan motor 102 is activated by the power supply connection or the locked protection recovery, it may occur that the fan motor 102 remains in the regeneration status φ_{RGN} without rotation due to the previous rotation stop location. Hence, it is desired that after the activation of the fan motor 102 and before the rotation of the fan motor 102 achieves a certain speed, the status of the regeneration controller 50 is controlled and set as null, and the first driving portion 20 and the second driving portion 30 are allowed to perform actions under the driving status φ_{DRV}.

Further, the regeneration controller 50 can also be set to be controlled externally so as to change the relationship between the turning number of the fan motor 102 and the duration of the regeneration period.

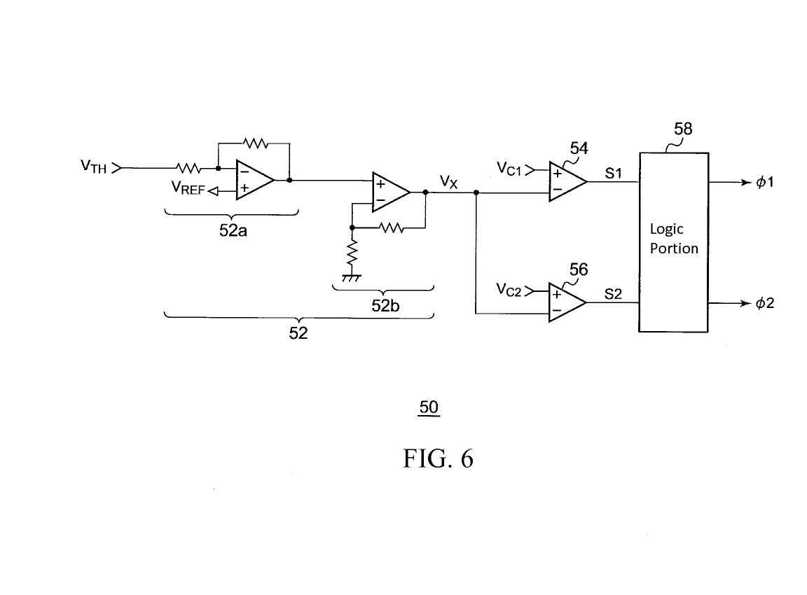

Subsequently, the regeneration controller 50 of the driving device 2 is discussed in an embodiment. FIG. 6 is a circuit diagram of the regeneration circuit 50 according to an embodiment.

The regeneration controller 50 controls the statuses of the first driving portion 20 and the second driving portion 30 based on a threshold voltage Vx corresponding to the turning number of the fan motor 102. The regeneration controller 50 includes a threshold voltage generation portion 52, a first comparator 54, a second comparator 56, and a logic portion 58.

The threshold voltage generation portion 52 generates a threshold voltage Vx having a positive correlation with the turning number of the fan motor 102. For example, the threshold voltage generation portion 52 generates a threshold voltage Vx based on an instruction signal V_{TH} having a negative correlation with the turning number of the fan motor 102, i.e. the higher voltage level of the instruction signal V_{TH} is corresponding to the lower turning number.

The threshold voltage generation portion 52 includes an inverting amplifier 52a for inversely amplifying the instruction signal V_{TH}, and a non-inverting amplifier 52b for non-inversely amplifying the output voltage of the inverting amplifier 52b. The output voltage and the threshold voltage Vx of the inverting amplifier 52a have positive correlation with the turning number of the fan motor 102.

The first comparator 54 compares the threshold voltage Vx having positive correlation with the turning number of the fan motor 102 with the first control signal V_{C1}, and generates a first examining signal S1 if the first control signal V_{C1} is determined to be lower. The second comparator 56 compares the threshold voltage Vx with the second control signal V_{C2}, and generates a second examining signal S2 if the second control signal V_{C2} is determined to be lower.

If the logic portion 58 determines the first examining signal S2 is generated, the first driving portion 20 is switched to the regeneration status φ_{RGN}; and if the logic portion 58 determines the examining signal S2 is generated, the second driving portion 30 is switched to the regeneration status φ_{RGN}.

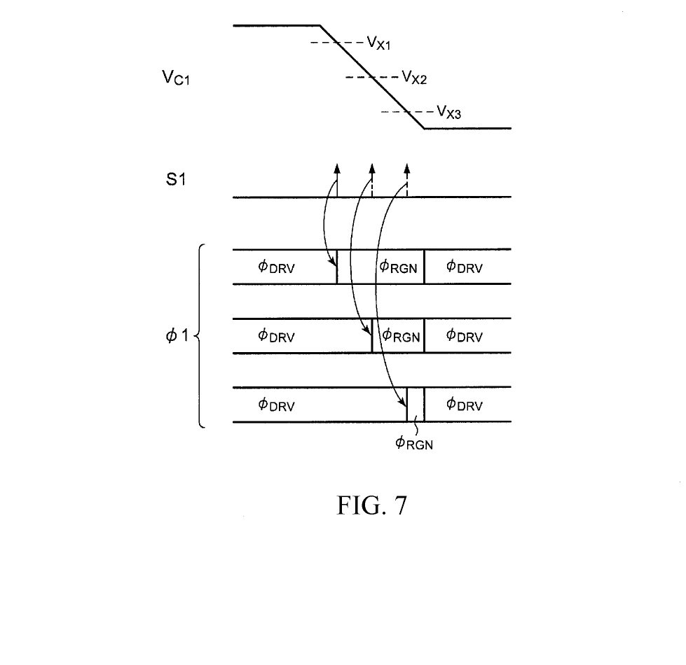

FIG. 7 shows actions of the regeneration controller 50 shown in FIG. 6. If the turning number of the fan motor 102 is greater, the threshold voltage Vx is higher, and the time sequence for determining the first examining signal S1 (S2) becomes earlier. In other words, if the turning number is greater, the time for switching the first driving portion 20 (the second driving portion 30) to the regeneration status φ_{RGN} is earlier, such that the duration of the regeneration period T_{RGN1} (T_{RGN2}) becomes longer.

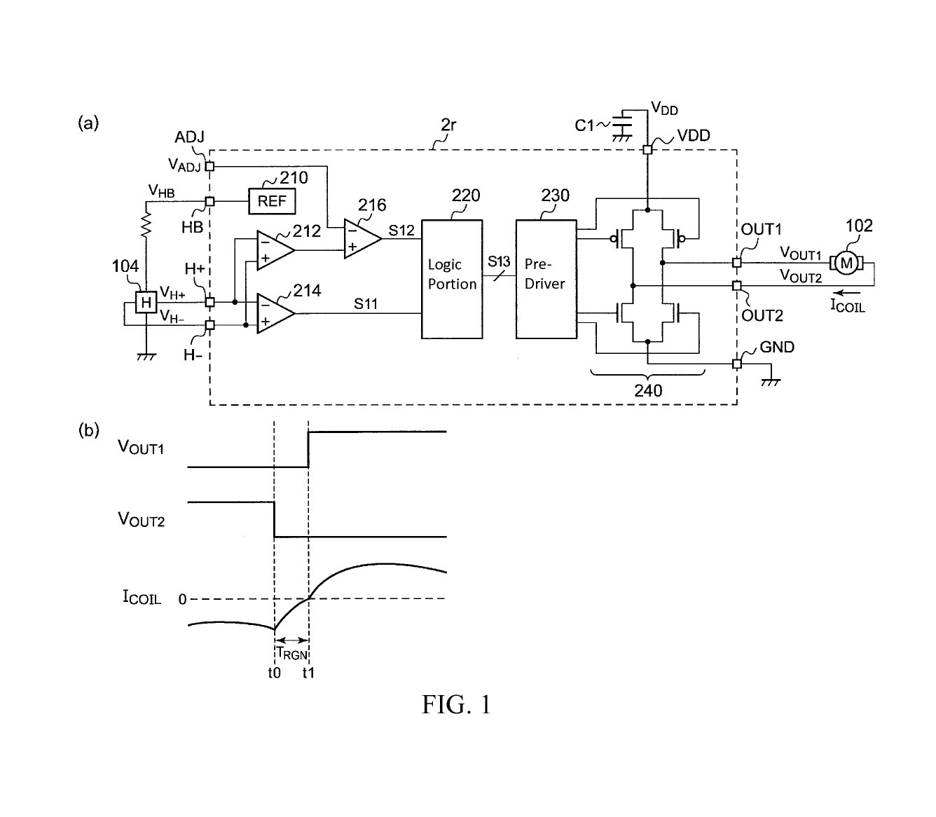

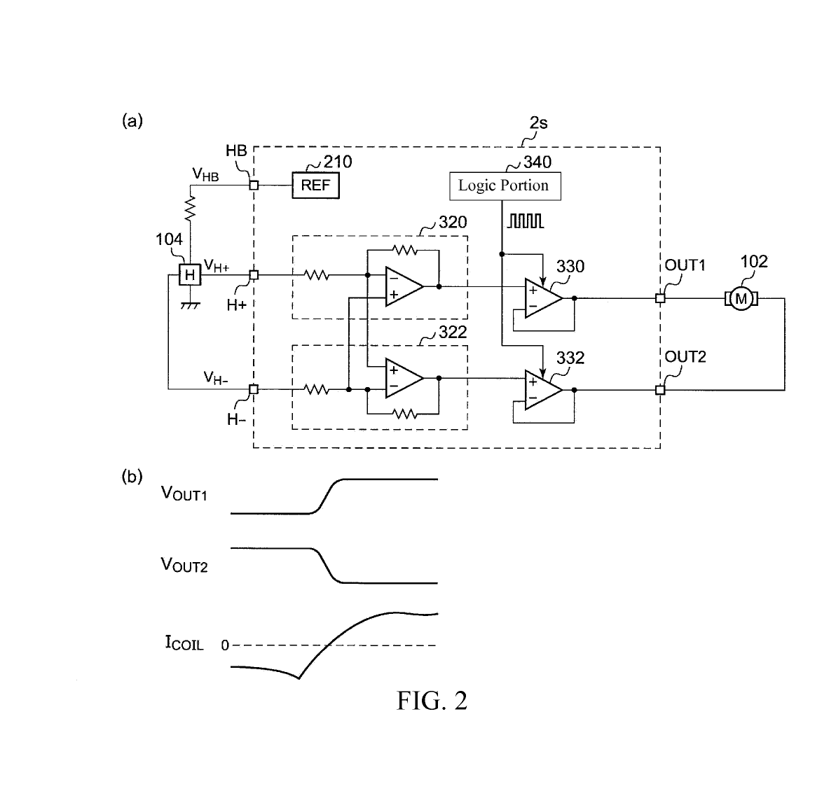

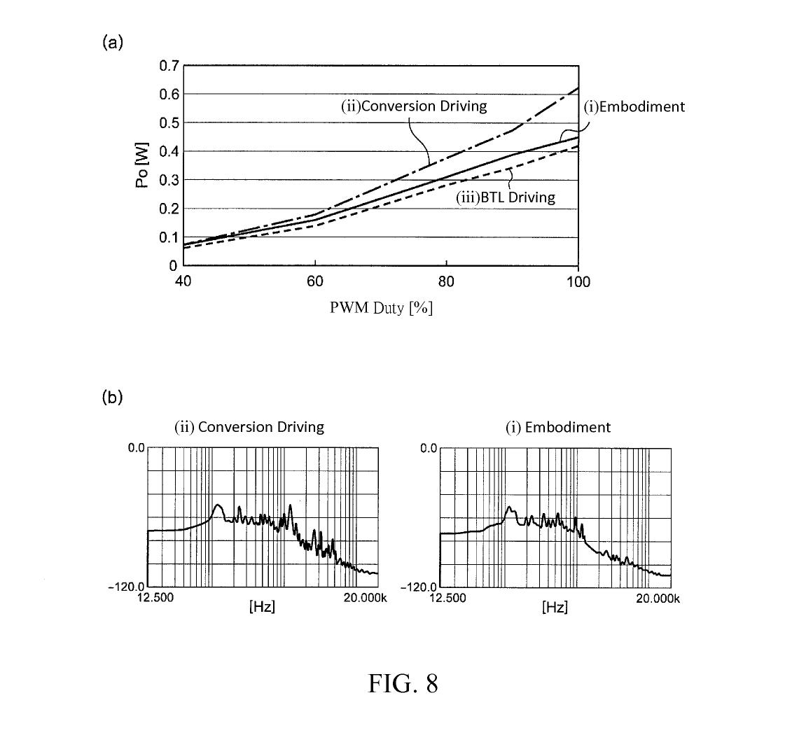

FIG. 8(a) shows the power consumption of the driving device 2 according to an embodiment, and FIG. 8(b) shows the noise frequency of the driving device 2 according to an embodiment. In FIG. 8(a), the solid line (i) indicates the power consumption of the driving device 2, the chain line (ii) indicates the power consumption of the driving device 2r using the conversion driving method shown in FIG. 1(a), and the dotted line (iii) indicates the power consumption of the driving device 2s shown in FIG. 2(a). The horizontal axis represents the duty cycle of the pulse signal S_{PWM} associated with the turning number of the fan motor 102.

As shown in FIG. 8(a), in comparison with the previous BTL driving method, the driving device 2 reduces about 28% of the power consumption, so as to enhance efficiency. Further, as shown in FIG. 8(b), in comparison with the previous conversion driving method, the driving device 2 reduces the noise level in a bandwidth between 1 kHz and 10 kHz.

Accordingly, the present invention is illustrated based on the above embodiments. It would be understood in the industry that these embodiments are exemplary illustrations, and various examples can be made to the combinations of each components or each processing steps. Further, these examples are also included in the scope of the present invention. The examples are discussed in the following descriptions.

### FIRST EXAMPLE

In this embodiment, situation which the instruction signal being an analog voltage indicating that the turning number having the negative correlation with the target value of the turning number is discussed, but the present invention is not limited thereto. For example, the instruction signal may also be an analog voltage indicating that the target value of the turning number of the fan motor 102 has a positive correlation with the turning number. In this situation, the threshold voltage generation portion 52 of FIG. 6 can be omitted.

Alternatively, the instruction signal may also be an external instruction pulse signal having a duty cycle corresponding to the target turning number. In this situation, if the duty cycle of the instruction pulse signal is greater, the duration of the regeneration period T_{RGN} is set longer. For example, based on the regeneration controller 50 shown in FIG. 6, the threshold voltage Vx is changed according to the duty cycle. For example, the threshold voltage generation portion 52 may also generate an analog voltage by using a filter for filtering external pulse signals, and generate a threshold voltage Vx based on the analog voltage. Alternatively, the threshold voltage generation portion 52 may also be constituted by a counter for determining a pulse width of an external pulse signal and a circuit for generating a threshold voltage Vx corresponding to a counting value.

### SECOND EXAMPLE

In this embodiment, the regeneration controller 50 controls the duration of the regeneration period based on the instruction signal V_{TH} indicating the turning number of the fan motor 102, but the present invention is not limited thereto. For example, the regeneration controller 50 may detect the current turning number of the fan motor 102, and then control the duration of the regeneration period according to the turning number detected.

When the fan motor 102 rotates at a constant speed, the coil current is correlated with the turning number. Hence, the regeneration controller 50 may also detect the current flowing to the coil of fan motor 102, and then control the duration of the regeneration period according to the amount of the coil current.

### THIRD EXAMPLE

In this embodiment, the regeneration period is set to be overlapped with the respective downward slopes of the first control signal V_{C1} and the second control signal V_{C2}, but the present invention is not limited thereto. For example, when the current phase shift is not an issue, overlapping with the downward slope can be replaced by overlapping with the front ends of the upward slope. In addition, the regeneration period can be set so as to overlap with the front ends of the upward slopes and with the downward slope.

### FOURTH EXAMPLE

In this embodiment, situation which the driving voltage V_{OUT} fixed at a predetermined voltage under the regeneration status φ_{RGN} is discussed, but the present invention is not limited thereto. The following examples may provide the actions of the first driving portion 20 and the second driving portion 30 under the regeneration status φ_{RGN}.

(1) Under the regeneration status φ_{RGN}, the output of the first driving portion and the second driving portion may also be set as a high resistance. In this situation, under the regeneration status φ_{RGN}, the coil current is regenerated via the body diodes of metal-oxide-semiconductor field effect transistors at the output segments of the first driving portion 20 and the second driving portion 30, respectively. In this situation, the control unit 40 can be simplified.

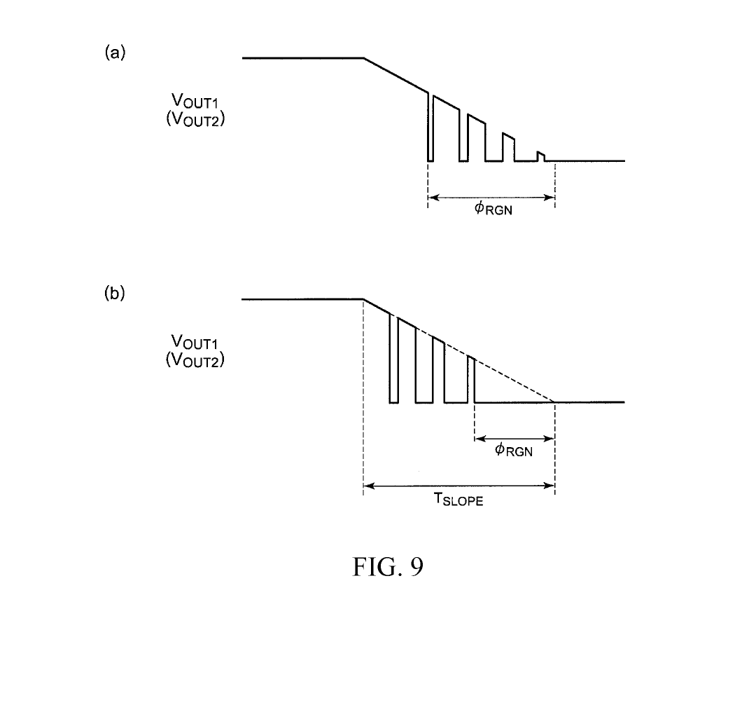

(2) FIG. 9(a) is a waveform diagram showing the driving voltage V_{OUT1} (V_{OUT2}) of the Fourth Example. Under the regeneration status φ_{RGN}, the first driving portion 20 may also be converted according to the following embodiment, i.e. the envelope of the output voltage V_{OUT1} is changed according to the first control voltage V_{C1}, and on the other hand, the duty cycle is gradually changed (decreased at the downward slope and increased at the upward slope). Similarly, the second driving portion 30 may also be converted according to the following embodiment, i.e. the envelope of the output voltage V_{OUT2} is changed according to the second control voltage V_{C2}, and on the other hand, the duty cycle is gradually changed. The conversion under the regeneration status φ_{RGN} and the PWM control for controlling the torque should be distinguished. Therefore, the silent property can be further enhanced.

### FIFTH EXAMPLE

FIG. 9(b) is a waveform diagram showing the driving voltage V_{OUT1} (V_{OUT2}) of the Fifth Example. The driving voltage V_{OUT1} may also be converted according to the following embodiment, i.e. in the period other than the first regeneration period T_{RGN1} in the slope of the first control signal V_{C1}, the duty cycle is gradually changed (decreased at the downward slope and increased at the upward slope). Similarly, the driving voltage V_{OUT2} may also be converted according to the following embodiment, i.e. in the period other than the second regeneration period T_{RGN2} in the slope period T_{SLOPE} of the second control signal V_{C2}, the duty cycle is gradually changed (decreased at the downward slope and increased at the upward slope). Further, the conversion and the PWM control for controlling the torque should be distinguished. Therefore, the silent property can be further enhanced.

### SIXTH EXAMPLE

In this embodiment, the turning number of the fan motor 102 is controlled based on the conversion of the pulse signal S_{pwm}, but the present invention is not limited thereto. For example, the turning number may also be controlled by varying the power source voltages V_{DD} of the first Hall amplifier 22 and the second Hall amplifier 32 at the output segments.

### SEVENTH EXAMPLE

The constitutions of the regeneration controller 50 are not limited to those shown in FIG. 6. For example, the regeneration controller 50 may also include a digital circuit. The digital regeneration controller 50 may also detect the rotation cycle of the fan motor 102, and multiply the parameter corresponding to the turning number of the fan motor 102 with the rotation period, so as to calculate the duration of the regeneration period.

### EIGHTH EXAMPLE

In this embodiment, situation where the cooling device 100 installed on the electronic machine for cooling the CPU is discussed. However, the present invention can be used in various applications for cooling heat-generating body rather than being limited to this embodiment. Specifically, the driving device 2 of the present embodiment is not limited to driving a fan motor, but can be used for driving other types of motors.

### NINTH EXAMPLE

In this embodiment, situation where the Hall element 104 installed outside the driving device 2 is discussed. However, the Hall element 104 may also be installed inside the driving device 2.

The present invention is illustrated by specific terms based on the embodiments. However, the embodiments only show the principles and applications of the present invention. Various changes or arrangements are allowed to implement the present invention without departing the scope or spirit of the present invention.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A fan motor driving device, characterized in that fan motors are driven based on a pair of out-of-phase Hall signals indicating locations of rotors of the symmetric fan motors from a Hall element, and comprising:
a first driving portion, configured to (i) amplify a difference of the pair of the Hall signals with a first polarity and generate a first control signal, and (ii) switch between a driving status and a regeneration status, wherein a first driving voltage corresponding to the first control signal is applied to one end of a coil of the fan motor in the driving status, and current flowing to the coil is regenerated at an output segment of the first driving portion in the regeneration status;
a second driving portion, configured to (i) amplify the difference of the pair of the Hall signals with a second polarity, and generate a second control signal, and (ii) switch between a driving status and a regeneration status, wherein a second driving voltage corresponding to the second control signal is applied to the other end of the coil of the fan motor, and current flowing to the coil is regenerated at an output segment of the second driving portion in the regeneration status; and
a regeneration controller, controlling statuses of the first driving portion and the second driving portion, respectively.

2. The fan motor driving device of claim 1, wherein the regeneration controller sets a first regeneration period at a downward slope of the first control signal, in which the first driving portion is set as the regeneration status during the first regeneration period, and the first driving portion is set as the driving status during periods other than the first regeneration period, and wherein the regeneration controller sets a second regeneration period at a downward slope of the second control signal, in which the second driving portion is set as the regeneration status during the second regeneration region, and the second driving portion is set as the driving status during periods other than the second regeneration period.

3. The fan motor driving device of claim 2, wherein the greater the turning number of the fan motor, the longer duration the regeneration controller sets for the first regeneration period and the second regeneration period.

4. The fan motor driving device of claim 1, wherein the first driving portion fixes the first driving voltage at a predetermined voltage under the regeneration status regardless of what the first control signal is; and the second driving portion fixes the second driving voltage at a predetermined voltage under the regeneration status regardless of what the second control signal is.

5. The fan motor driving device of claim 1, wherein outputs of the first driving portion and the second driving portion become high resistance under the regeneration status.

6. The fan motor driving device of claim 1, wherein the first driving portion converts the first driving voltage according to the following: an envelope of the first driving voltage is changed based on the first control signal, and a duty cycle of the first driving voltage gradually changes; and
the second driving portion converts the second driving voltage according to the following: an envelope of the second driving voltage is changed based on the second control signal, and a duty cycle of the second driving voltage gradually changes.

7. The fan motor driving device of claim 1, wherein the regeneration controller comprises:
a first comparator, comparing a threshold voltage corresponding to the turning number of the fan motor with the first control signal, and generating a first examining signal if the first control signal is determined to be lower;
a second comparator, comparing the threshold voltage with the second control signal, and generating a second examining signal if the second control signal is determined to be lower; and
a logic portion, switching the first driving portion to the regeneration status if the first examining signal is generated, and switching the second driving portion to the regeneration status if the second examining signal is generated.

8. The fan motor driving device of claim 1, wherein the regeneration controller controls statuses of the first driving portion and the second driving portion, respectively, according to an instruction signal indicating the turning number of the fan motor.

9. The fan motor driving device of claim 8, wherein the instruction signal is a lower value if a target value of the turning number of the fan motor is higher; and
the regeneration controller further comprises:
an inverse amplifying circuit for inversely amplifying the instruction signal, so as to generate a threshold voltage.

10. The fan motor driving device of claim 1, wherein the regeneration controller controls statuses of the first driving portion and the second driving portion, respectively, according to an examining signal indicating the current turning number of the fan motor.

11. The fan motor driving device of claim 1, wherein the regeneration controller controls statuses of the first driving portion and the second driving portion, respectively, according to current flowing to the fan motor.

12. The fan motor driving device of claim 1, wherein the first driving portion comprises a first Hall amplifier for non-inversely amplifying a difference of the pair of the Hall signals so as to generating the first control signal; and
a second driving portion comprises a second Hall amplifier for inversely amplifying the difference of the pair of the Hall signals so as to generate the second control signal.

13. The fan motor driving device of claim 12, wherein a gain of the first Hall amplifier is set as that the first control signal is inclined in a phase switching period and flat in periods other than the phase switching period; and
a gain of the second Hall amplifier is set as that the second control signal is inclined in the phase switching period and flat in periods other than the phase switching period.

14. The fan motor driving device of claim 1, wherein the regeneration controller fixes the first driving portion and the second driving portion to the driving status during an initial activation period of the fan motor.

15. The fan motor driving device of claim 4, wherein the predetermined voltage is at a low voltage level.

16. The fan motor driving device of claim 1, being integrally formed on a semiconductor substrate.

17. A cooling device, characterized in that comprising:
a fan motor;
a Hall element, generating a pair of Hall signals indicating a location of a rotor of the fan motor; and
a fan motor driving device of claim 1, driving the fan motor based on the pair of the Hall signals.

18. An electronic machine, characterized in that comprising:
a processor;
a fan motor disposed opposingly to the processor;
a Hall element, generating a pair of Hall signals indicating a location of a rotor of the fan motor; and
a fan motor driving device of claim 1, driving the fan motor based on the pair of the Hall signals.

19. A method for driving a fan motor, characterized in that comprising:
generating a pair of out-of-phase Hall signals indicating a location of a rotor of the fan motor by a Hall element;
amplifying a difference of the pair of the Hall signals with a first polarity and generating a first control signal;
applying a first driving voltage corresponding to the first control signal to one end of a coil of the fan motor, and setting a first regeneration period at a downward slope of the first control signal, so as to regenerate current of the coil;
amplifying the difference of the pair of the Hall signals with a second polarity and generating a second control signal;
applying a second driving voltage corresponding to the second control signal to the other end of the coil of the fan motor, and setting a second regeneration period at a downward slope of the second control signal, so as to regenerate current of the coil; and
controlling, by setting longer duration for the first regeneration period and the second regeneration period when a turning number of the fan motor is greater.

20. The method of claim 19, wherein the controlling operation comprises:
comparing a threshold voltage corresponding to the turning number of the fan motor with the first control signal, and determining a first examining signal if the first control signal is lower;
comparing the threshold voltage with the second control signal, and determining a second examining signal if the second control signal is lower; and
switching to the first regeneration period if the first examining signal is determined, and switching to the second regeneration period if the second examining signal is determined.
